(19) United States
(12) Patent Application Publication
(10) Pub. No.: US 2026/0206461 A1
(43) Pub. Date: Jul. 16, 2026

(54) DISPLAY DEVICE AND MANUFACTURING METHOD THEREFOR

(71) Applicants: Chengdu BOE Optoelectronics Technology Co., Ltd., Chengdu, Sichuan (CN); BOE Technology Group Co., Ltd., Beijing (CN)

(72) Inventors: Yi ZHANG, Beijing (CN); Haotian YANG, Beijing (CN); Xiaodong HAO, Beijing (CN); Wei GONG, Beijing (CN); Xiangdong WEI, Beijing (CN); Wei LIU, Beijing (CN); Danyang BI, Beijing (CN); Han ZHANG, Beijing (CN); Peng YANG, Beijing (CN); Kang WANG, Beijing (CN); Xiaoxia LIU, Beijing (CN); Jiaming SHEN, Beijing (CN); Chuxiang WANG, Beijing (CN); Xiaoliang FU, Beijing (CN)

(21) Appl. No.: 18/855,493

(22) PCT Filed: Jan. 3, 2024
(86) PCT No.: PCT/CN2024/070367

§ 371 Date: Oct. 9, 2024

(30) Foreign Application Priority Data
Jan. 19, 2023 (CN) 202310097900.1

(51) Int. Cl. H10K 59/80

(52) U.S. Cl. CPC H10K 59/8722; H10K 59/873

(57) ABSTRACT

A display device and a method for manufacturing a display device are provided. The display device includes: a display module including a non-casting area and a casting area at least partially around the non-casting area; and an injection molding edge sealing portion, arranged on a non-light-emitting side of the display module and located in an area of the casting area close to the non-casting area. The injection molding edge sealing portion includes an edge sealing glue arranged around the non-casting area, and the edge sealing glue is configured to seal with an injection mold.

### CROSS-REFERENCE TO RELATED APPLICATIONS

This application is a national phase entry under 35 U.S.C. § 371 of International Application No. PCT/CN2024/070367 filed on Jan. 3, 2024, which claims priority to Chinese patent application No. 202310097900.1, filed with the State Intellectual Property Office of China on Jan. 19, 2023 and entitled “Display device and manufacturing method therefor”, the entire contents of which are incorporated herein by reference.

### TECHNICAL FIELD

The present application relates to the technical field of display devices, and in particular to a display device and a manufacturing method therefor.

### BACKGROUND

At present, assembling an AMOLED watch module with a whole machine is mainly through bonding a cover plate on a display module to a middle frame. However, in order to avoid the influence of the connection between the display module and the middle frame on the display function of the display panel, this method of fixing the display module and the middle frame requires reserving a safety distance between the middle frame and an edge of the display panel, which will affect the narrow bezel design of the whole machine.

### SUMMARY

The present application provides a display device and a manufacturing method therefor.

This application provides the following technical solutions.

A display device, including:
a display module, including a non-casting area and a casting area at least partially around the non-casting area;
an injection molding edge sealing portion, arranged on a non-light-emitting side of the display module and located in an area of the casting area close to the non-casting area.

The injection molding edge sealing portion includes an edge sealing glue. The edge sealing glue is arranged around the non-casting area and is configured to seal with an injection mold.

In some embodiments, the injection molding edge sealing portion further includes a limiting member. The limiting member includes a first baffle and a second baffle. The first baffle is located on a side of the edge sealing glue close to the non-casting area and is arranged around the non-casting area. The second baffle is located on a side of the edge sealing glue away from the non-casting area and is arranged around the edge sealing glue.

The height of the edge sealing glue along the first direction is smaller than the height of the first baffle plate and the second baffle plate along the first direction. The first direction is the thickness direction of the display module.

In some embodiments, the display module includes a display panel. The limiting member further includes a bottom plate. The bottom plate is located between the edge sealing glue and the non-light-emitting side of the display panel and is arranged around the non-casting area. The side of the bottom plate close to the non-casting area is connected to the first baffle, and the side of the bottom plate away from the non-casting area is connected to the second baffle.

In some embodiments, the injection molding edge sealing portion further includes an adhesive layer. The adhesive layer is located on a side of the injection molding edge sealing portion facing a non-light-emitting side of the display panel. The injection molding edge sealing portion is connected to the display module via the adhesive layer.

In some embodiments, the edge sealing glue is at least one of epoxy resin glue, thermosetting glue, ultraviolet light curing glue, or moisture curing glue.

In some embodiments, the edge sealing glue is a hot melt glue.

In some embodiments, the display module further includes a cover plate and a circuit board. The cover plate is arranged on a light-emitting side of the display panel. The display panel includes a main body and a bonding portion. The main body is located between the cover plate and the circuit board. The bonding portion is folded to a side of the main body away from the cover plate and is connected to the circuit board.

The injection molding edge sealing portion is located at a side of the bonding portion away from the main body.

In some embodiments, an assembly gap is provided between the display module and an area where the injection molding edge sealing portion overlaps with the edge of the bonding portion.

The display device further includes a sealant filled in the assembly gap.

In some embodiments, the injection molding edge sealing portion is arranged around the circuit board.

In some embodiments, a height of the edge sealing glue along the first direction is greater than or equal to a thickness of the circuit board.

In some embodiments, a packaging portion is further included. The packaging portion is located on the non-light-emitting side of the display module and is injection-molded and packaged in the casting area. The packaging portion wraps part of the edge sealing glue of the injection molding edge sealing portion away from the non-casting area.

In some embodiments, a middle frame is further included. The middle frame is provided with a receiving cavity for placing the display module. The display module is fixedly connected to the middle frame through the packaging portion.

The present application further provides a method for manufacturing a display device by using an injection mold. The injection mold includes a side shell, a connecting shell and a mold head. The side shell is sleeve-shaped and encloses a receiving space. The mold head is located in the receiving space and is configured to cooperate with an edge sealing glue of an injection molding edge sealing portion. The connecting shell is located between the side shell and the mold head. One end of the mold head is connected to one end of the side shell through the connecting shell.

The method includes:
providing an injection molding edge sealing portion on the non-light-emitting side of the display module, where the injection molding edge sealing portion is located in an area of the casting area close to the non-casting area, and the injection molding edge sealing portion includes an edge sealing glue arranged around the non-casting area;
placing an assembly of the display module and the injection molding edge sealing portion in the receiving space of the injection mold, where the inner wall of the side shell is in sealing contact with the edge of the display module, the end of the mold head away from the connecting shell is inserted into the liquid edge sealing glue of the injection molding edge sealing portion, and the mold head is not in contact with the display module, and the injection molding edge sealing portion, the mold head, the connecting shell, the side shell and the display module cooperate to form a sealed injection molding cavity;
curing the liquid edge glue;
injecting liquid injection molding material into the sealed injection molding cavity;
curing the liquid injection molding material to form a packaging portion;
disassembling the injection mold.

In some embodiments, providing an injection molding edge sealing portion on the non-light-emitting side of the display module includes:
coating a liquid edge sealing glue to the area of the casting area close to the non-casting area on the display module.

In some embodiments, the liquid edge sealing glue is at least one of epoxy resin glue, thermosetting glue, ultraviolet light curing glue, or moisture curing glue.

In some embodiments, when the edge sealing glue is a hot melt glue, after the injection molding edge sealing portion is provided on the non-light-emitting side of the display module, the method includes:
heating and melting the edge sealing glue in the injection molding edge sealing portion to form a liquid edge sealing glue.

A display device and a manufacturing method therefor provided in embodiments of the present application include a display module and an injection molding edge sealing portion. The display module includes a non-casting area and a casting area around the non-casting area. The injection molding edge sealing portion is arranged on the non-light-emitting side of the display module and is located in the area of the casting area close to the non-casting area. The injection molding edge sealing portion includes an edge sealing glue arranged around the non-casting area. The edge sealing glue is configured to seal with the injection mold. When it is necessary to form an edge sealing portion by injection molding in the casting area of the display module, when the injection mold is assembled, the mold head on the injection mold that originally needs to have an interference fit with the display device can be inserted into the edge sealing glue of the injection molding edge sealing portion without contacting the display module. The injection mold, the casting area of the display module and the injection molding edge sealing portion form an injection molding cavity. The sealing effect of the injection molding edge sealing portion can completely isolate the casting area from the non-casting area. In the process of casting the injection molding material into the injection molding cavity, the injection molding material can be prevented from entering the non-casting area. In addition, since the mold head of the injection mold does not contact the display module during the injection molding process, the mold head of the injection mold does not generate an extrusion force on the display module, and there is no risk of mold mark on the display device.

### BRIEF DESCRIPTION OF THE DRAWINGS

FIG. 1 is a schematic structural diagram of the structure of a display device provided in an embodiment of the present application;

FIG. 2 is a schematic diagram of the structure of a display device provided in an embodiment of the present application;

FIG. 3 is a schematic diagram of an assembly of a display module and an injection mold provided in an embodiment of the present application;

FIG. 4 is a state diagram of a display module provided in an embodiment of the present application;

FIG. 5 is a schematic diagram of a planar structure of a display device provided in an embodiment of the present application;

FIG. 6 is a schematic diagram of an assembly of a display device and an injection mold provided in an embodiment of the present application;

FIG. 7 is a state diagram of a display device in an injection molding process provided in an embodiment of the present application;

FIG. 8 is an exploded view of a display device provided in an embodiment of the present application;

FIG. 9 is a cross-sectional view of a display device provided in an embodiment of the present application;

FIG. 10 is a schematic diagram of the structure of an injection molding edge sealing portion provided in an embodiment of the present application;

FIG. 11 is a cross-sectional view of a display device provided in an embodiment of the present application;

FIG. 12 is a schematic diagram of the structure of a display device provided in an embodiment of the present application;

FIG. 13 is a schematic diagram of the structure of a display device provided in an embodiment of the present application;

FIG. 14 is a schematic diagram of a planar structure of a display device provided in an embodiment of the present application;

FIG. 15 is a cross-sectional view of a display device provided in an embodiment of the present application;

FIG. 16 is a schematic diagram of an assembly of a display device and an injection mold provided in an embodiment of the present application;

FIG. 17 is a flow chart of a method for manufacturing a display device provided in an embodiment of the present application;

FIG. 18 is an enlarged view of region E in FIG. 6.

### REFERENCE NUMBERS

1—display module; 11—cover plate; 12—polarizer; 13—display panel; 131—main body; 132—bonding portion; 14—composite film layer; 15—circuit board; 16—optical glue; 17—spacer; A1—non-casting area; A2—casting area; 2—injection molding edge sealing portion; 21—edge sealing glue; 221—first baffle plate; 222—second baffle plate; 223—bottom plate; 23—adhesive layer; 3—injection mold; 31—mold head; 32—side shell; 33—connecting shell; 301—lower mold frame; 302—lower mold core; 303—upper mold frame; 304—upper mold core; 305—glue inlet; 306—glue outlet; 4—injection molding material; 5—sealant; 6—packaging portion; Q-injection molding cavity; J—assembly gap.

### DETAILED DESCRIPTION

The technical solutions in embodiments of the present application will be clearly and completely described below in conjunction with the drawings in the embodiments of the present application. Obviously, the described embodiments are only part of embodiments of the present application, rather than all embodiments. Based on the embodiments described in this application, all other embodiments obtained by those of ordinary skill in the art without making any creative work shall fall within the protection scope of the present application.

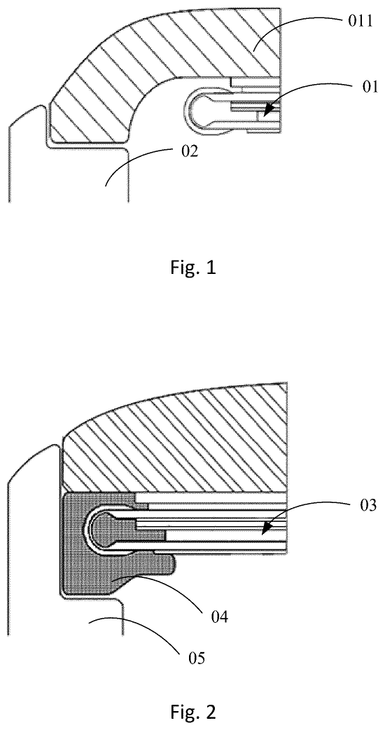

In the related art, FIG. 1 is a schematic diagram illustrating bonding of the cover plate 011 of the display module 01 and the middle frame 02. As shown in FIG. 1, a safety distance needs to be reserved between the middle frame 02 and the display panel in the display module 01, which is not conducive to the narrow bezel design of the display device as a whole machine. In order to reduce the bezel of the whole machine, edge injection molding (Insert Molding) technology is used, as shown in FIG. 2. The injection molding material is casted into the edge area of the display module 03 in an injection molding process, so as to form a packaging portion 04 of the whole machine assembly. The formed packaging portion 04 enters the interior of the display module, and there is no need to reserve a safety distance between the casting area and the display area. By bonding the middle frame 05 to the packaging portion 04, the bezel of the whole machine can be reduced.

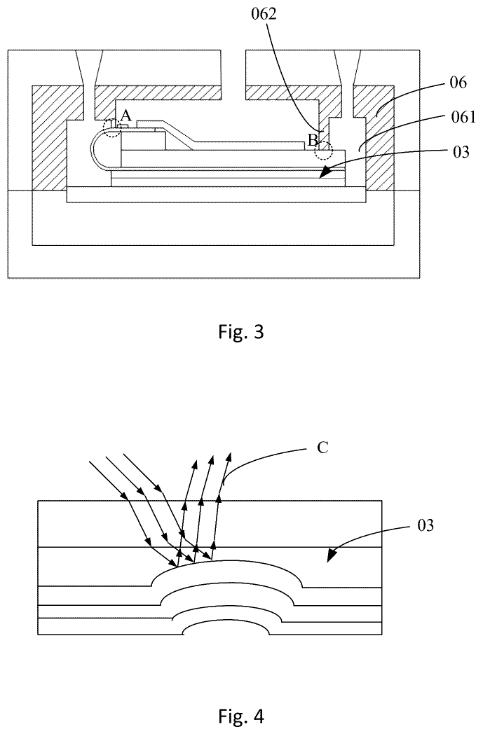

The process of forming the packaging portion at the edge of the display module by the injection molding technology is as follows. The first step is to clean the surface of the display module to maintain the cleanliness of the surface of the display module. The second step is to put the display module into the mold, that is, put the display module into the injection mold and assemble the injection mold, so that the display module cooperates with the injection mold to form an injection molding cavity. The third step is to perform injection molding. The injection molding material is filled into the injection molding cavity through the glue inlet on the injection mold. When the injection molding material overflows from the glue outlet on the injection mold, it indicates that the injection molding cavity is full of the injection molding material. The fourth step is to cure the injection molding material by high temperature. The fifth step is to remove the residual material from the glue inlet and glue outlet of the injection mold. The fifth step is demolding, that is, to disassemble the display module from the injection mold, so as to complete the entire injection molding process. The state of the injection mold and the display module after being assembled in the above second to fourth steps is as shown in FIG. 3. The inventors of the present application found that during the injection molding process, in order to prevent the injection molding material from overflowing from the injection molding cavity 061, the mold head 062 of the injection mold 06 that contacts the surface of the display module 03 needs to have an interference fit with the display module 03, such as in area A and area B of FIG. 3. During the high-temperature curing process, due to the interference fit between the injection mold 06 and the display module 03, the injection mold will have an extrusion force on the product, which will cause a slight deformation of the display module, and further cause uneven scattering of light C on the surface of the display module, as shown in FIG. 4, which will manifest as a light and dark phenomenon of the display image of the display module, i.e., a mold mark problem.

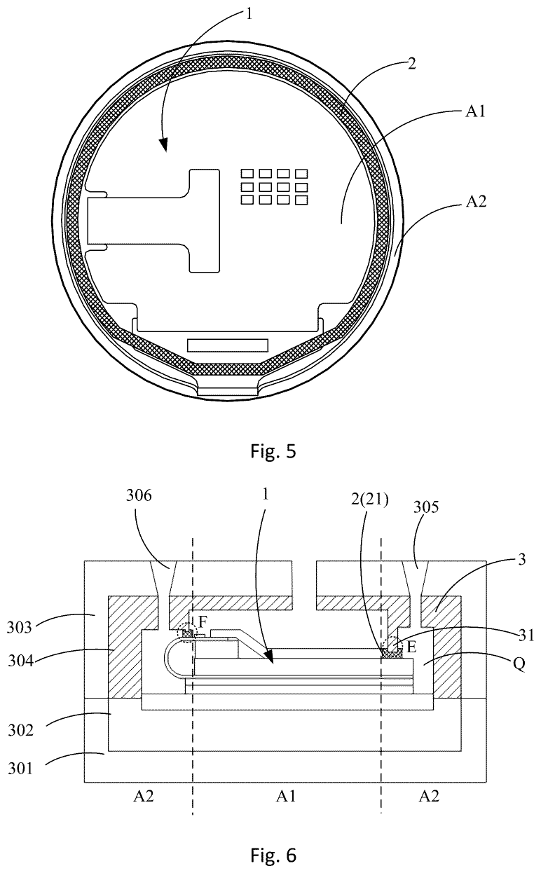

In order to solve the above problem, the present application provides a display device, as shown in FIG. 5. The display device includes a display module 1 and an injection molding edge sealing portion 2.

The display module 1 includes a non-casting area A1 and a casting area A2 at least partially around the non-casting area A1.

The injection molding edge sealing portion 2 is arranged on the non-light-emitting side of the display module 1 and is located in an area of the casting area A2 close to the non-casting area A1. The injection molding edge sealing portion 2 includes an edge sealing glue 21, which is arranged around the non-casting area A1. The edge sealing glue 21 is configured to seal with the injection mold.

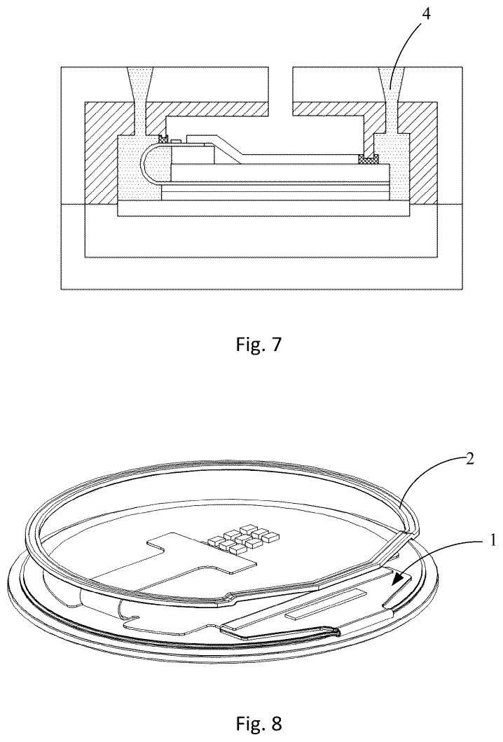

The display device provided in the embodiments of the present application includes a display module 1 and an injection molding edge sealing portion 2. The display module 1 includes a non-casting area A1 and a casting area A2 at least partially around the non-casting area A1. The injection molding edge sealing portion 2 is arranged on the non-light-emitting side of the display module 1 and is located in an area of the casting area A2 close to the non-casting area A1. The injection molding edge sealing portion 2 includes an edge sealing glue 21 arranged around the non-casting area A1. The edge sealing glue 21 is configured to seal with the injection mold. When it is necessary to form an edge sealing portion by injection molding in the casting area A2 of the display module 1, and when the injection mold is assembled, as shown in FIG. 6, the mold head 31 of the injection mold 3 that originally needs to have an interference fit with the display device is inserted into the edge sealing glue 21 of the injection molding edge sealing portion 2 without contacting the display module 1. The injection mold 3, the casting area A2 of the display module 1 and the injection molding edge sealing portion 2 form an injection molding cavity Q. The sealing effect of the injection molding edge sealing portion 2 completely isolates the casting area A2 from the non-casting area A1. In the process of casting the injection molding material 4 into the injection molding cavity Q, as shown in FIG. 7, the injection molding material 4 can be prevented from entering the non-casting area A1. In addition, since the mold head of the injection mold 3 does not contact the display module 1 during the injection molding process, the mold head of the injection mold 3 does not generate an extrusion force on the display module 1, and there is no risk of mold mark on the display device.

The above-mentioned display module 1 has a display area and a non-display area around the display area. Since the injection molding material 4 casted in the casting area A2 is actually casted on the non-light-emitting side of the display module 1, it has no effect on the display function of the display module 1. Therefore, part of the casting area A2 of the above-mentioned display module 1 may overlap with the display area of the display module 1, and there is no need to reserve a safety distance between the casting area A2 and the display area, thereby greatly reducing the bezel of the display device.

In some embodiments of the present application, as shown in FIG. 6, the above-mentioned injection molding edge sealing portion 2 may only include the edge sealing glue 21. That is, while manufacturing the display device, the liquid edge sealing glue 21 may be directly coated in the casting area A2 of the display module 1. During the assembly of the injection mold 3, the mold head 31 of the injection mold 3 is inserted into the liquid edge sealing glue 21, and no extrusion force is generated on the display module 1. After the edge sealing glue 21 is cured, the display module 1 and the injection mold 3 can be sealed, and the injection mold 3 has no pressure applied to the display module 1 in the sealing process, which can completely avoid the risk of mold mark while performing the injection molding process.

In the above structure, the material of the edge sealing glue 21 is at least one of epoxy resin glue, thermosetting glue, ultraviolet light curing glue (UV glue) and moisture curing glue, etc., and other adhesive systems that meet the requirements can also be used, which is not limited here. The composition of epoxy resin glue may be single-component or two-component. Adding a curing agent to the liquid epoxy resin glue can make the liquid epoxy resin glue cured. Thermosetting glue is liquid at room temperature and can be cured by high-temperature curing. The curing temperature can be selected according to the selected glue system. For example, a glue system with a curing temperature of about 70° C. can be used. UV curing glue is liquid at room temperature and can be cured by ultraviolet irradiation. Moisture curing glue can be cured by leaving it at room temperature.

Optionally, as shown in FIGS. 8, 9 and 10, the above-mentioned injection molding edge sealing portion 2 may further include a limiting member. The limiting member may have a first baffle 221 and a second baffle 222. The first baffle 221 is at a side of the edge sealing glue 21 close to the non-casting area A1 and is arranged around the non-casting area A1. The second baffle 222 is at a side of the edge sealing glue 21 away from the non-casting area A1 and is arranged around the edge sealing glue 21. The height of the edge sealing glue 21 along the first direction is less than the height of the first baffle 221 and the second baffle 222 along the first direction. The first direction is the thickness direction of the display module 1. The first baffle 221 and the second baffle 222 can prevent the edge sealing glue 21 from flowing to other areas when the edge sealing glue 21 is in liquid state.

The materials of the first baffle plate 221 and the second baffle plate 222 may be plastic, such as PET plastic, or metal, etc., which is not limited here and depends on the actual situation.

In some embodiments, the display module includes a display panel. As shown in FIG. 10, the above-mentioned limiting member may further include a bottom plate 223, which is located between the edge sealing glue 21 and the non-light-emitting side of the display panel and is arranged around the non-casting area A1. The side of the bottom plate 223 close to the non-casting area A1 is connected to the first baffle 221, and the side of the bottom plate 223 away from the non-casting area A1 is connected to the second baffle 222. The bottom plate 223 may serve as a carrying component of the edge sealing glue 21. The limiting member encloses a placement space for the edge sealing glue 21. The limiting member may be formed by stamping of metal material.

It should be noted that the above-mentioned casting area A2 at least partially surrounds the non-casting area A1, and the injection molding edge sealing portion 2 is located in the casting area A2. Then, the edge sealing glue 21, the first baffle 221, the second baffle 222 and the bottom plate 223 in the injection molding edge sealing portion are arranged around the non-casting area A1, which means that they are arranged around the non-casting area A1 in the casting area A2. The shape structure of the first baffle 221, the second baffle 222 and the bottom plate 223 may be determined according to the shape of the casting area A1. For example, if the casting area A2 semi-surrounds the non-casting area A1, the structure in the injection molding edge sealing portion 2 also semi-surrounds the non-casting area A1, and if the casting area A2 fully surrounds the non-casting area A1, the structure in the injection molding edge sealing portion 2 is also correspondingly arranged to fully surround the non-casting area A1.

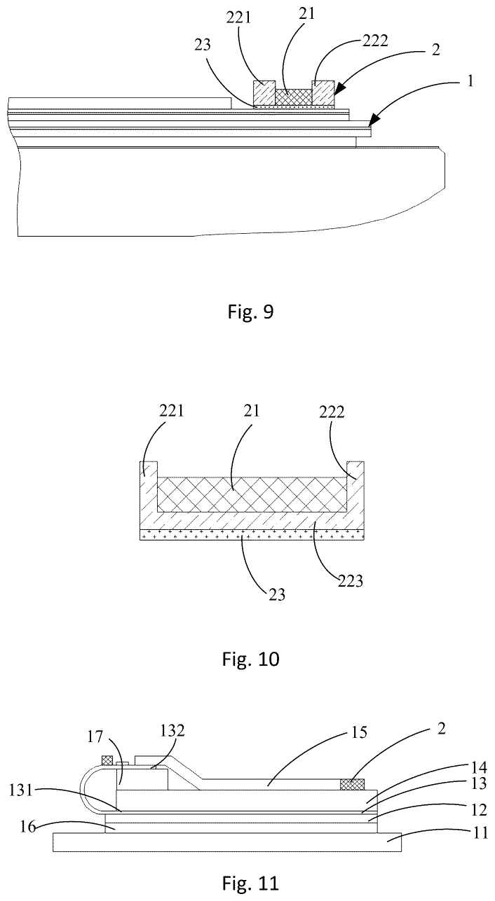

In some embodiments, as shown in FIGS. 8 and 9, the above-mentioned injection molding edge sealing portion 2 may further include an adhesive layer 23. The adhesive layer 23 is located at the side of the injection molding edge sealing portion 2 facing the non-light-emitting side of the display panel. The injection molding edge sealing portion 2 may be connected to the display module 1 through the adhesive layer 23 to ensure fixed bonding between the edge sealing portion and the display module 1.

When the limiting member does not include a bottom plate 223, the first baffle plate 221 and the second baffle plate 222 may be directly bonded to the adhesive layer, as shown in FIG. 9. The adhesive layer 23 has the function of carrying the edge sealing glue 21. The injection molding edge sealing portion 2 may be assembled to the display module 1 through the adhesive layer 23. When the limiting member includes a bottom plate 223. The bottom plate 223 is bonded to the adhesive layer 23. The injection molding edge sealing portion 2 is assembled to the display module 1 through the adhesive layer 23, as shown in FIG. 10. In some embodiments, the adhesive layer 23 may be a pressure sensitive adhesive (PSA) or be made of other materials, which are not limited here.

In some embodiments, when the injection molding edge sealing portion 2 includes the limiting member, the material of the edge sealing glue 21 may also be at least one of epoxy resin glue, thermosetting glue, ultraviolet light curing glue (UV glue) and moisture curing glue, etc. In the process of manufacturing the display device, the limiting member is bonded to the adhesive layer 23, and then bonded to the display module 1, and then the edge sealing glue 21 is coated in the space enclosed by the limiting member.

In addition, when the injection molding edge sealing portion 2 includes the limiting member, the edge sealing glue 21 may also be a hot melt glue, which is solid at room temperature and becomes a flowable liquid when heated to a certain temperature. Different types of hot melt glues have different melting points, which are roughly distributed between 65° and 135°. In addition, the softening and curing speeds of hot melt glues are very fast. The hot melt glues can be melted or cured within a few seconds, which makes their application in the injection molding process of display devices has less impact on production time. In actual applications, hot melt glues with curing temperatures generally in the range of 60° C. to 65° C. are used. In the process of manufacturing the display device, the edge sealing glue 21, the limiting member and the adhesive layer 23 are assembled together, and then directly bonded to the display module 1. Before the display device and the injection mold 3 are assembled, the hot melt glue needs to be melted to facilitate the insertion of the mold head 31 of the injection mold 3 into the edge sealing glue 21 without generating an extrusion force on the display module 1. This can achieve sealing between the display device and the injection mold 3 and completely avoid the influence of mold mark.

In some embodiments of the present application, as shown in FIG. 11, the above-mentioned display module 1 may include a cover plate 11, a display panel 13 and a circuit board 15. The cover plate 11 is covered on the light-emitting side of the display panel 13. The display panel 13 may include a main body 131 and a bonding portion 132. The main body 131 is between the cover plate 11 and the circuit board 15. The bonding portion 132 is folded to a side of the main body 131 away from the cover plate 11 to be connected to the circuit board 15. The injection molding edge sealing portion 2 may be located on a side of the bonding portion 132 away from the main body 131, so that a mold mark is not produced on the display module during the injection molding process.

For example, the above-mentioned display module 1 may include a cover plate (CG) 11, a polarizer (POL) 12, a display panel (PNL) 13, a composite film layer (SCF) 14 and a circuit board 15. The polarizer 12 is on the light-emitting side of the main body 131 of the display panel. The composite film layer 14 is on the non-light-emitting side of the main body 131 of the display panel. The cover plate 11 is covered on the side of the polarizer 12 away from the main body 131 of the display panel. The cover plate 11 and the polarizer 12 may be bonded by optical glue 16. The circuit board 15 is on the side of the composite film layer 14 away from the main body 131 of the display panel. The bonding portion 132 of the display panel is folded to the side of the composite film layer 14 away from the main body 131 of the display panel and connected to the circuit board 15. A spacer 17 may also be arranged between the bonding portion 132 and the composite film layer 14. The injection molding edge sealing portion 2 is on the side of the bonding portion 132 away from the main body 131.

The composite film layer 14 may include an adhesive layer, a foam layer, a polyimide layer, a metal layer, etc., which are sequentially arranged on the non-light-emitting side of the main body of the display panel. The circuit board may be a flexible circuit board (FPC).

In some embodiments, as shown in FIGS. 9 and 11, the edge of the circuit board 15 may be retracted relative to the edge of the composite film layer 14. The injection molding edge sealing portion 2 may be arranged around the circuit board 15. The injection molding edge sealing portion 2 may be fixedly bonded to the side of the composite film layer 14 away from the main body 131 of the display panel. As shown in FIG. 11, when the injection molding edge sealing portion 2 only includes the edge sealing glue 21, during the process of coating the edge sealing glue 21, the inner side of the edge sealing glue 21 may contact the edge of the circuit board 14, and the edge of the circuit board is used to prevent the flow of the edge sealing glue 21. When the injection molding edge sealing portion 2 includes a limiting member, as shown in FIG. 8, the limiting member limits the flow of the edge sealing glue 21, thus the position of the injection molding edge sealing portion 2 may not be restricted by the position of the edge of the circuit board, and the injection molding edge sealing portion 2 may not contact the edge of the retracted circuit board.

Furthermore, optionally, when the injection molding edge sealing portion 2 includes a limiting member, the circuit board 15 may not be retracted inward, and the injection molding edge sealing portion 2 may be fixedly bonded to the side of the circuit board 15 away from the composite film layer 14, and the sealing requirement may still be achieved. The position of the injection molding edge sealing portion 2 is not limited here and is determined according to actual situation.

In some embodiments, the height of the edge sealing glue 21 in the injection molding edge sealing portion 2 along the first direction may be greater than or equal to the thickness of the circuit board. For example, when the injection molding edge sealing portion 2 only includes the edge sealing glue 21, since the edge of the circuit board needs to be used to prevent the flow of the edge sealing glue 21 during the coating process of the edge sealing glue 21, the height of the edge sealing glue 21 along the first direction is equal to the thickness of the circuit board. When the injection molding edge sealing portion 2 includes a limiting member, and the limiting member limits the flow of the edge sealing glue 21, the height of the edge sealing glue 21 along the first direction can be set according to the height of the limiting member along the first direction. The height of the edge sealing glue 21 in the injection molding edge sealing portion 2 along the first direction can be set to be greater than or equal to the thickness of the circuit board, which can ensure the effectiveness of the sealing of the injection molding edge sealing portion 2, or the height of the edge sealing glue 21 in the injection molding edge sealing portion 2 along the first direction can be set to be less than the thickness of the circuit board, depending on the actual situation.

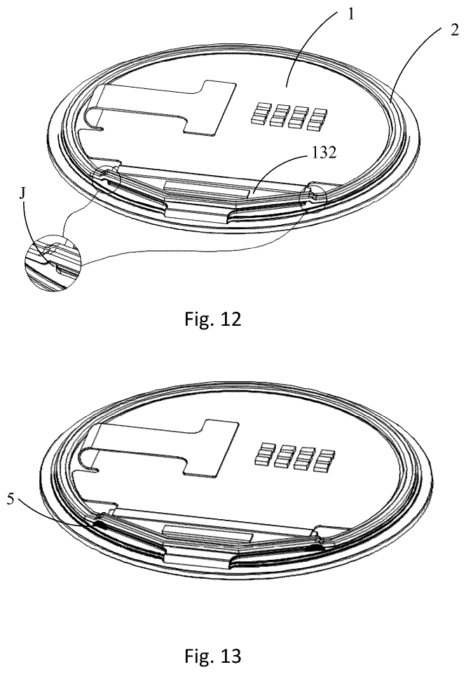

In some embodiments of the present application, there is an assembly gap J between the area where the injection molding edge sealing portion 2 and the edge of bonding portion 132 overlap and the display module 1, as shown in FIG. 12. That is, the injection molding edge sealing portion 2 on the left and right sides of the bonding portion 132 on the display module 1 has a height difference, so that the injection molding edge sealing portion 2 and the surface of the display module have an assembly gap J. The display device may further include a sealant 5 filled in the assembly gap J, as shown in FIG. 13, which can prevent the injection molding material 4 from leaking out during the injection molding process.

In some embodiments, the sealant 5 may be formed in an adhesive dispensing process, and may be automatically dispensed using equipment or manually dispensed. The sealant may be ultraviolet light curing glue (UV glue) or Tuffy glue, etc., which is not limited here, and depends on actual situation.

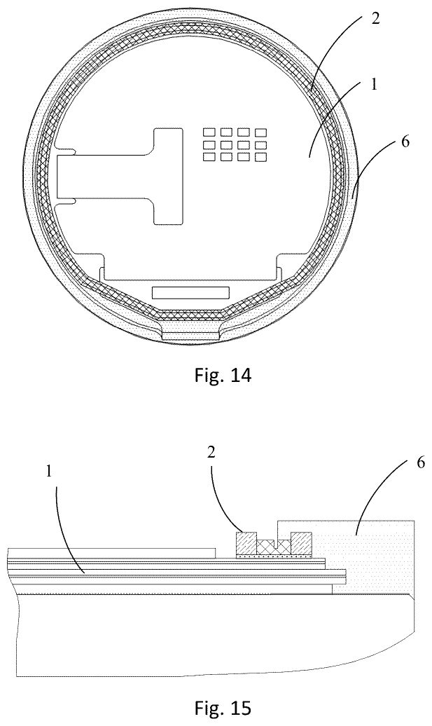

In some embodiments of the present application, a packaging portion 6 is also included. As shown in FIGS. 14 and 15, the packaging portion 6 is on the non-light-emitting side of the display module and is injection-molded and packaged in the casting area. The packaging portion wraps part of the edge sealing glue of the injection molding edge sealing portion away from the non-casting area. In some embodiments, the packaging portion 6 is formed at the edge of the display module on the non-light-emitting side through cooperation between the injection mold and the injection molding edge sealing portion. In this way, after the display device is manufactured, the packaging portion 6 wraps the part of the edge sealing glue away from the non-casting area. For example, when the injection molding edge sealing portion is only the edge sealing glue, the packaging portion 6 only wraps a part of the edge sealing glue. When the injection molding edge sealing portion includes a limiting member, the packaging portion 6 wraps the part of the edge sealing glue away from the non-casting area and the second baffle. By sealing between the injection molding edge sealing portion 2 of display device and the injection mold 3, a packaging portion 6 injection-molded and packaged in the casting area A2 of the display module 1 is formed. This can prevent the injection molding material 4 forming the packaging portion 6 from overflowing into the non-casting area A1, and can also avoid the formation of mold marks on the display device, thereby improving product quality.

In some embodiments of the present application, a middle frame is also included. The middle frame has a receiving cavity for placing the display module. The display module 1 is fixedly connected to the middle frame through the packaging portion 6, so that a narrow bezel design can be achieved.

The above-mentioned display device may be an AMOLED wearable product or a tablet, a mobile phone, etc., which is not limited here.

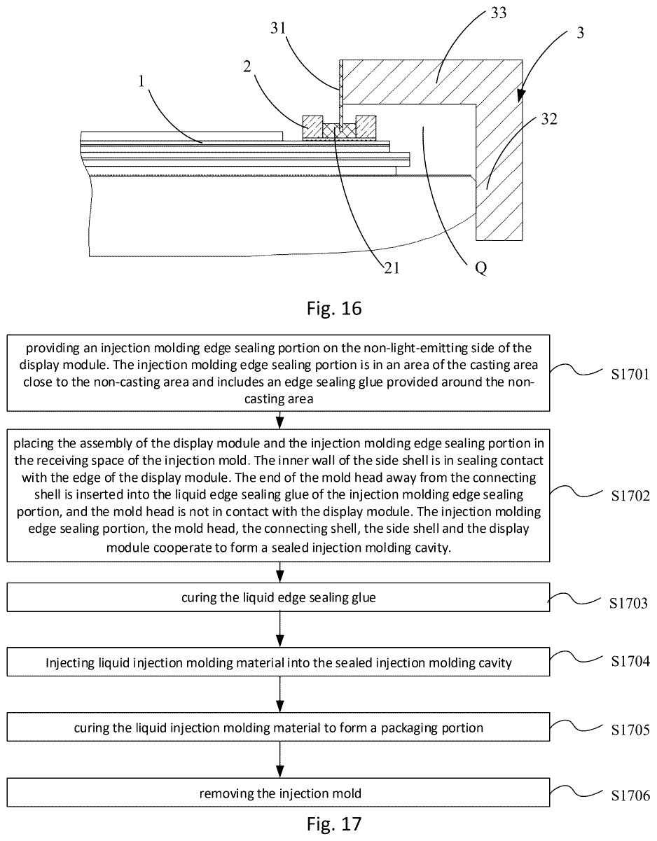

The present application further provides a method for manufacturing a display device using an injection mold 3. As shown in FIG. 16, the injection mold 3 may include a side shell 32, a connecting shell 33 and a mold head 31. The side shell 32 is sleeve-shaped and encloses a receiving space. The mold head 31 is in the receiving space and is configured to cooperate with the edge sealing glue of the injection molding edge sealing portion. The connecting shell 33 is between the side shell 32 and the mold head 31. One end of the mold head 31 is connected to one end of the side shell 32 through the connecting shell 33.

In some embodiments, as shown in FIG. 6, the injection mold 3 may be formed by combining an upper mold and a lower mold. The lower mold may include a lower mold frame 301 and a lower mold core 302, and the upper mold may include an upper mold frame 303 and an upper mold core 304. The side shell 32, connecting shell 33 and mold head 31 may be formed on the upper mold core 304. A glue inlet 305 and a glue outlet 306 may be formed on the upper mold.

The method for manufacturing the display device, as shown in FIG. 17, may include the following operations.

S1701: providing an injection molding edge sealing portion 2 on the non-light-emitting side of the display module 1. The injection molding edge sealing portion is in an area of the casting area close to the non-casting area. The injection molding edge sealing portion 2 includes an edge sealing glue 21 provided around the non-casting area A1. In some embodiments, before the injection molding edge sealing portion 2 is provided, the surface of the display module 1 is cleaned, so as to ensure the cleanliness of the surface of the display module 1.

S1702: placing the assembly of the display module 1 and the injection molding edge sealing portion 2 in the receiving space of the injection mold 3, as shown in FIG. 6 or FIG. 16. The inner wall of the side shell 32 is in sealing contact with the edge of the display module 1. The end of the mold head 31 away from the connecting shell 33 is inserted into the liquid edge sealing glue 21 of the injection molding edge sealing portion 2, and the mold head 31 is not in contact with the display module 1. The injection molding edge sealing portion 2, the mold head 31, the connecting shell 33, the side shell 32 and the display module 1 cooperate to form a sealed injection molding cavity Q. The edge of the display module 1 may be the edge of the cover plate, that is, when the display device is assembled with the injection mold 3, the inner wall of the side shell 32 is in sealing contact with the edge of the upper cover plate of the display module 1.

S1703: curing the liquid edge sealing glue 21 to ensure the sealing effect of the injection molding cavity Q.

S1704: Injecting liquid injection molding material 4 into the sealed injection molding cavity Q, as shown in FIG. 7. The injection molding material 4 may be casted into the injection mold 3 through the glue inlet 305 of the molding mold 3. When the injection molding material 4 overflows from the glue outlet 306, it indicates that the injection molding cavity Q is full of the injection molding material 4. The injection molding material may be a resin material.

S1705: curing the liquid injection molding material 4 to form a packaging portion 6.

S1706: disassembling the injection mold 3 to complete the entire injection molding process. Before the injection mold 3 is disassembled, the residual injection molding material 4 at the glue inlet 305 and the glue outlet 306 needs to be cleared.

In the method for manufacturing the injection molding packaging structure, when the injection mold 3 is assembled, the mold head 31 on the injection mold 3 that originally needs to have an interference fit with the display device can be inserted into the edge sealing glue 21 of the injection molding edge sealing portion 2 without contacting the display module 1. The injection mold 3, the casting area A2 of the display module 1 and the injection molding edge sealing portion 2 form a sealed injection molding cavity Q. The sealing effect of the injection molding edge sealing portion 2 can completely isolate the casting area A2 from the non-casting area A1. In the process of casting the injection molding material 4 into the injection molding cavity Q, the injection molding material 4 can be prevented from entering the non-casting area A1. In addition, since the mold head of the injection mold 3 does not contact the display module 1 during the injection molding process, the mold head of the injection mold 3 does not generate an extrusion force on the display module 1, and there is no risk of mold mark on the display module.

In some embodiments of the present application, providing an injection molding edge sealing portion 2 on the non-light-emitting side of the display module 1 in S1701 includes: coating a liquid edge sealing glue 21 in the area of the casting area A2 close to the non-casting area A1 on the display module 1. That is, the injection molding edge sealing portion 2 is directly provided by coating the liquid edge sealing glue 21 on the display module 1.

The injection molding edge sealing portion 2 may or may not include a limiting member. The liquid edge sealing glue 21 may be at least one of epoxy resin glue, thermosetting glue, ultraviolet light curing glue or moisture curing glue. In some embodiments, the composition of epoxy resin glue may be single-component or two-component. Adding a curing agent to the liquid epoxy resin glue can make the liquid epoxy resin glue cured. Thermosetting glue is liquid at room temperature and can be cured by high-temperature curing. The curing temperature can be selected according to the selected glue system. For example, a glue system with a curing temperature of about 70° C. can be used. UV curing glue is liquid at room temperature and can be cured by ultraviolet irradiation. Moisture curing glue can be cured by leaving it at room temperature.

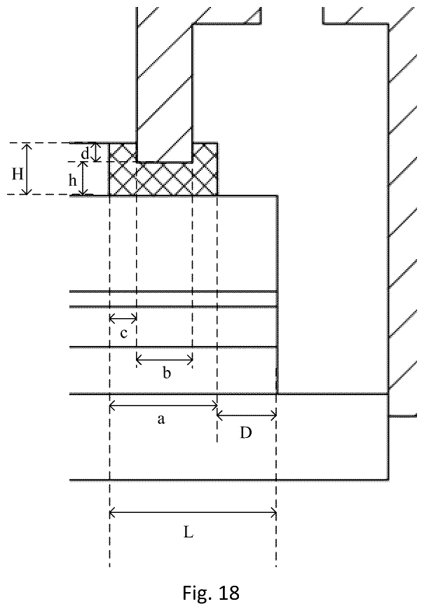

In some embodiments, when the injection molding edge sealing portion 2 on the display device only includes edge sealing glue, in the area where the injection molding edge sealing portion 2 does not contact the bonding portion 132 of the display panel, as shown in FIG. 18, the coating width ‘a’ of the edge sealing glue 21 can be determined according to the distance that the circuit board is retracted compared to the outer edge of the main body of the display panel, a=L−D. L is the distance between the outer edge of the circuit board and the outer edge of the main body of the display panel, the design range of which can be 2.0 mm to 3.5 mm. For example, L is 2.3 mm in actual application. D is the distance between the edge of the injection molding and the outer edge of the main body of the display panel, and it can be D=0.9 mm in actual application. The coating height H of the edge sealing glue 21 can be determined according to the design thickness of the circuit board, and may be consistent with the design thickness of the circuit board. The flow of the edge sealing glue 21 is limited by the edge of the circuit board. The thickness range of the circuit backplane can be 0.12 mm to 0.285 mm, and the height H in actual application can be 0.15 mm. When the injection mold 3 is designed, the distance between the mold head 31 and the surface of the display module 1 is h=H−d. The mold head 31 is designed according to the coating height. The mold head 31 is pressed into the edge sealing glue 21. In actual application, the pressed-in distance between the mold head and the edge sealing glue 21 is d=0.03 mm, that is, the mold head is pressed into the edge sealing glue 21 to a depth of 0.03 mm. The width of the mold head 31 can be b=0.5 mm in actual application. The glue width ‘c’ on both sides of the mold head 31 is the same, which can be c=(L−D−b)/2. ‘c’ may be 0.45 mm in actual application. The specific parameter values of the above a, L, D, H, h, d, b, and c can be determined according to actual situation and are not limited here.

The area where the injection molding edge sealing portion 2 contacts the bonding portion 132 of the display panel is shown as area F in FIG. 6. Due to the thickness difference between the area of the display device where a bonding portion exist and the area of the display device where the bonding portion does not exist, the coating height of the edge sealing 21 in the area F can be H₁=H−T_{B}−T_{P}. The coating width and the pressed-in distance between the mold head 31 and the edge sealing glue 21 in the area F are consistent with those in the area where the injection molding edge sealing portion 2 does not contact the bonding portion of the display panel. T_{B} is the thickness of the spacer, which can be 0.064 mm in actual application. T_{P} is the thickness value of the bonding portion 132, which can be 0.024 mm in actual application. As mentioned above, the coating height H in actual application can be 0.15 mm, and then the coating height H₁ can be 0.064 mm.

In some embodiments, in order to reduce the coating width of the edge sealing glue 21, the mold head 31 can be set to be a thin sheet, as shown in FIG. 16, which is conducive to reducing the coating width of the edge sealing glue 21 and can save more space for the assembly of the whole machine.

In some embodiment of the present application, when the edge sealing glue 21 is a hot melt glue, the injection molding edge sealing portion 2 needs to include a limiting member. After the injection molding edge sealing portion 2 is provided on the non-light-emitting side of the display module 1, the operation S1701 further includes: heating and melting the edge sealing glue 21 in the injection molding edge sealing portion 2 to form a liquid edge sealing glue 21.

Hot melt glue is solid at room temperature and becomes a flowable liquid when heated to a certain temperature. Different types of hot melt glues have different melting points, which are roughly distributed between 65° and 135°. In addition, the softening and curing speeds of hot melt glues are very fast, and they can be melted or cured within a few seconds. This makes their application in the injection molding process of display devices has less impact on production time. In actual applications, hot melt glues with curing temperatures generally in the range of 60° C. to 65° C. can be used.

Obviously, those skilled in the art can make various changes and modifications to the embodiments of the present application without departing from the spirit and scope of the present application. Thus, if these modifications and variations of the present application fall within the scope of the claims of the present application and their equivalent technologies, the present application is also intended to include these modifications and variations.

1. A display device, comprising:
a display module, comprising a non-casting area and a casting area at least partially around the non-casting area;
an injection molding edge sealing portion, arranged on a non-light-emitting side of the display module and located in an area of the casting area close to the non-casting area; wherein the injection molding edge sealing portion comprises an edge sealing glue arranged around the non-casting area, and the edge sealing glue is configured to seal with an injection mold.

2. The display device according to claim 1, wherein the injection molding edge sealing portion further comprises a limiting member, the limiting member comprises a first baffle and a second baffle, the first baffle is located on a side of the edge sealing glue close to the non-casting area and is arranged around the non-casting area, and the second baffle is located on a side of the edge sealing glue away from the non-casting area and is arranged around the edge sealing glue;
a height of the edge sealing glue along the first direction is smaller than a height of the first baffle plate and the second baffle plate along the first direction, and the first direction is a thickness direction of the display module.

3. The display device according to claim 2, wherein the display module comprises a display panel, and the limiting member further comprises a bottom plate;
the bottom plate is between the edge sealing glue and a non-light-emitting side of the display panel, and is arranged around the non-casting area; a side of the bottom plate close to the non-casting area is connected to the first baffle, and a side of the bottom plate away from the non-casting area is connected to the second baffle.

4. The display device according to claim 3, wherein the injection molding edge sealing portion further comprises an adhesive layer;
the adhesive layer is on a side of the injection molding edge sealing portion facing the non-light-emitting side of the display panel, and the injection molding edge sealing portion is connected to the display module via the adhesive layer.

5. The display device according to claim 1, wherein the edge sealing glue is at least one of epoxy resin glue, thermosetting glue, ultraviolet light curing glue or moisture curing glue.

6. The display device according to claim 2, wherein the edge sealing glue is a hot melt glue.

7. The display device according to claim 1, wherein the display module further comprises a display panel, a cover plate and a circuit board;
the cover plate is arranged on a light-emitting side of the display panel;
the display panel comprises a main body and a bonding portion, the main body is between the cover plate and the circuit board, and the bonding portion is folded to a side of the main body away from the cover plate and is connected to the circuit board;
the injection molding edge sealing portion is on a side of the bonding portion away from the main body.

8. The display device according to claim 7, wherein an assembly gap exists between the display module and a region where the injection molding edge sealing portion overlaps with an edge of the bonding portion;
the display device further comprises a sealant filled in the assembly gap.

9. The display device according to claim 7, wherein the injection molding edge sealing portion is arranged around the circuit board.

10. The display device according to claim 9, wherein a height of the edge sealing glue along a first direction is greater than or equal to a thickness of the circuit board.

11. The display device according to claim 1, further comprising:
a packaging portion,
wherein the packaging portion is on the non-light-emitting side of the display module and is injection-molded and packaged in the casting area, and the packaging portion wraps part of the edge sealing glue of the injection molding edge sealing portion away from the non-casting area.

12. The display device according to claim 11, further comprising:
a middle frame,
wherein the middle frame is provided with a receiving cavity for placing the display module, and the display module is fixedly connected to the middle frame through the packaging portion.

13. A method for manufacturing a display device, wherein an injection mold is used, the injection mold comprises a side shell, a connecting shell and a mold head;
wherein the side shell is sleeve-shaped and encloses a receiving space,
the mold head is in the receiving space and is configured to cooperate with an edge sealing glue of an injection molding edge sealing portion,
the connecting shell is between the side shell and the mold head, and one end of the mold head is connected to one end of the side shell through the connecting shell;
wherein the method comprises:
providing an injection molding edge sealing portion on a non-light-emitting side of a display module, wherein the injection molding edge sealing portion is in an area of a casting area close to a non-casting area, and comprises an edge sealing glue arranged around the non-casting area;
placing an assembly of the display module and the injection molding edge sealing portion in the receiving space of the injection mold, wherein an inner wall of the side shell is in sealing contact with an edge of the display module, an end of the mold head away from the connecting shell is inserted into a liquid edge sealing glue of the injection molding edge sealing portion, the mold head is not in contact with the display module, and the injection molding edge sealing portion, the mold head, the connecting shell, the side shell and the display module cooperate to form a sealed injection molding cavity;
curing the liquid edge sealing glue;
injecting liquid injection molding material into the sealed injection molding cavity;
curing the liquid injection molding material to form a packaging portion;
disassembling the injection mold.

14. The method according to claim 13, wherein said providing the injection molding edge sealing portion on the non-light-emitting side of the display module comprises:
coating the liquid edge sealing glue to the area of the casting area close to the non-casting area on the display module.

15. The method according to claim 14, the liquid edge sealing glue is at least one of epoxy resin glue, thermosetting glue, ultraviolet light curing glue or moisture curing glue.

16. The method according to claim 13, wherein the edge sealing glue is a hot melt glue, and after providing the injection molding edge sealing portion on the non-light-emitting side of the display module, the method further comprises:
heating and melting the edge sealing glue of the injection molding edge sealing portion form the liquid edge sealing glue.
